(19) United States
(12) Patent Application Publication
(10) Pub. No.: US 2025/0174549 A1
(43) Pub. Date: May 29, 2025

(54) SVIA FORMATION USING VFTL SCHEME

(71) Applicant: International Business Machines Corporation, Armonk, NY (US)

(72) Inventors: Yann Mignot, Slingerlands, NY (US); Joe Lee, Niskayuna, NY (US); Sylvie Mignot, Slingerlands, NY (US); Brian Conerney, Ballston Lake, NY (US); Adam Gennett, Halfmoon, NY (US)

(21) Appl. No.: 18/522,736

(22) Filed: Nov. 29, 2023

(51) Int. Cl. H01L 23/522; H01L 21/311; H01L 21/768; H01L 23/532

(52) U.S. Cl. CPC H01L 23/5226; H01L 21/31144; H01L 21/76802; H01L 21/76879; H01L 23/53228; H01L 23/53257; H01L 23/53261

(57) ABSTRACT

A semiconductor device structure and related method forming super via (SVIA) structures using a via first, trench last (VFTL) damascene processing technique. The formed SVIA connects a top metallization level structure formed in a stack of interlevel dielectric (ILD) material layers and extends through an intermediate ILD layer and a dielectric etch stop layer therebetween to connect to an underlying metallization level structure of an underlying ILD layer below the intermediate ILD layer. The VFTL processing to form the SVIA avoids a punching through of an etch stop layer provided between the intermediate ILD layer and the bottom ILD material layer after a final trench and OPL strip. The SVIA further includes a metal plug contacting the underlying metallization level structure of the underlying ILD layer and is of a material different than the material of said metallization level structure. The formed SVIA exhibits a straight via profile and chamfer.

### FIELD OF THE INVENTION

The present invention generally relates to integrated circuits (ICs) that comprise sub-level wirings and/or devices, and methods for fabricating same. More specifically, the present invention relates to semiconductor structures that include skip via or super via structures to enable better interconnect between metal line levels and improved signal routing capability including footprint reduction and higher current delivery to lower line levels and improved chamfer structure.

### BACKGROUND OF THE INVENTION

Integrated circuit (IC) designs typically comprise multiple levels of wirings and/or devices that are isolated from one another by an inter-level dielectric (ILD) and are interconnected by multiple metal vias therebetween. The levels at which the wirings and/or devices are located are typically referred to as the “line levels,” while the levels at which the metal vias are located are typically referred to as the “via levels.”

As IC chips are aggressively scaled, the density of wiring and/or devices at the line levels increases significantly and gradually reaches the maximum density allowed for optimal device performance.

There is a continuing need for further reducing the sizes of the IC chips without adversely affecting the device performance.

FIG. 3 shows a conventional Via First Trench Last (VFTL) semiconductor device integration scheme and a portion of a resulting semiconductor device structure including VFTL metallization, e.g., Copper, formed in overlying inter-level dielectric (ILD) layers 6, 8. Formed using VFTL damascene processing steps in the top ILD layer 8 of the structure are metallization (line) structures 2 and corresponding via portions 3 that each connect to corresponding metallization line structures 5 formed in an immediate underlying ILD layer 6. As shown in FIG. 3, metallization structure 2 can connect to structure 1 with the formation of two separate vias and trenches defined by a VTFL scheme. However, a conventional VTFL scheme to form a super via (SVIA) 9 can not be achieved because during the process the via etch stops on the cap layer 7 in order to avoid a direct contact of trench patterning scheme (OPL, resist) with the Copper preventing Copper defects and resist poisoning. Further, current VFTL damascene processing results in a chamfered (i.e., angled) via profile 4.

### SUMMARY OF THE INVENTION

The present disclosure, in one aspect relates to an integrated circuit (IC) semiconductor device structure and method for forming a “super via” (SVIA) structure in accordance with a damascene Via First Trench Last (VFTL) processing scheme.

In one aspect, the SVIA structure is formed in a back end and far back-end of semiconductor manufacturing line (BEOL and FBEOL) processing levels that provides for better interconnect and signal routing (including device footprint reduction and higher current delivery to lower levels).

In a further aspect, there is provided a semiconductor structure and method that includes the simultaneous forming of one or more instances of via connections including the “super via” or “skip via” structure that is a via directly interconnecting two metal levels that are spaced apart and skips over an intervening metal level.

In an aspect, the slope or via chamfer angle of the via and SVIA structure connecting two metallization levels is straighter than produced in conventional methods because no dielectric cap or etch stop layer is required after a final trench etch as these layers have been already etched during the Via etch part then refill and protected by a metal plug.

The present disclosure further relates to a super via structure formed to include a metal plug to prevent copper migration and resist poisoning. In an embodiment, the metal plug is cobalt and formed according to a self deposition technique within a formed super via opening.

In accordance with a first aspect of the present disclosure, there is provided a method of forming a semiconductor structure. The method comprises: providing an initial semiconductor structure comprising a stack of inter-level dielectric (ILD) material layers including a top ILD layer, a bottom ILD layer and one or more intermediate ILD layers therebetween, one or more ILD material layers of the stack including a metallization level of metal structures; forming via openings in the top ILD material layer, the corresponding formed via opening located above a corresponding metallization level metal structure of an underlying ILD layer of the stack, at least one via opening extending through two or more intermediate ILD material layers of the stack, each formed via opening extending to expose a surface of the corresponding metallization level metal structure in the underlying ILD level; depositing, within each formed via opening, a metal material to form a metal plug having a top surface below a top surface of the corresponding formed via opening, the deposited metal plug material in the formed via opening directly contacting a top surface of the corresponding metallization level metal structure; forming an organic planarization (OPL) layer above the top ILD layer, the OPL layer extending to completely fill each formed via opening; forming one or more trench openings at a top surface of the formed OPL layer, each trench opening formed directly above a corresponding formed via opening; stripping the OPL layer including removing the OPL material within each formed via opening; forming corresponding top metallization level trench openings at a surface of the top ILD material layer; and depositing a metal material within each corresponding top metal level trench openings in the third ILD layer and within a remaining space of each formed via opening.

In accordance with a further aspect of the present disclosure, there is provided a semiconductor structure. The semiconductor structure comprises: a first inter-level dielectric (ILD) material layer including a first metallization level of metal structures; a second ILD material layer formed atop the first inter-level dielectric material layer, the second inter-level dielectric material layer including a second metallization level of metal structures; a third ILD material layer formed atop the second inter-level dielectric material layer, the third inter-level dielectric material layer including a third metallization level of metal structures; a metal via structure directly interconnecting a third metallization level metal structure to a top surface of a second metallization level metal structure in the second ILD material layer, the metal via structure comprising a top portion of a first metal material and a bottom portion of a second metal material connecting the top surface of the second metallization level metal structure; and a metal super via (SVIA) structure directly interconnecting a third metallization level metal structure to a top surface of a first metallization level metal structure in the first ILD material layer, the metal SVIA structure comprising a top portion of a first metal material and a bottom portion of a second metal material connecting the top surface of the first metallization level metal structure.

In accordance with a further aspect of the present disclosure, there is provided a method of forming an integrated circuit (IC) device. The method comprises: providing an initial semiconductor structure comprising a first inter-level dielectric (ILD) material layer including a first metallization level of metal structures and a second ILD material layer formed atop the first inter-level dielectric material layer, the second inter-level dielectric material layer including a second metallization level of metal structures; forming a third ILD material layer formed atop the second inter-level dielectric material layer; forming via openings in the third ILD material layer, the corresponding formed via opening located above a corresponding second metallization level metal structure and extending to expose a surface of the second metallization level metal structure in the second ILD material layer; forming super via openings in the third ILD material layer, the formed super via opening extending through the second ILD material layer located above a corresponding first metallization level metal structure and exposing a surface of the first metallization level metal structure in the first ILD material layer; depositing, within each formed via and super via opening, a metal material to form a plug of a pre-determined height below a surface of the corresponding via or super via opening, the formed metal plug in the via opening directly contacting a top surface of a corresponding second metallization level metal structure and the formed metal plug in the super via opening directly contacting a top surface of a corresponding first metallization level metal structure; depositing, within remaining space of each formed via and super via opening, an organic planarization layer (OPL) material that completely fills each via and super via opening and extends to form an OPL layer above the third ILD material layer; forming top metal level trench openings at a top surface of the formed OPL layer, each top metal level trench opening formed directly above a corresponding formed via or super via opening in the third ILD material layer; stripping the OPL layer including removing the OPL material within each opening; forming corresponding top metal level trench openings at a top surface of the third ILD material layer; and depositing a metal material within each corresponding top metal level trench openings in the third ILD layer and within a remaining space of each formed via and super via opening.

Other aspects, features and advantages of the invention will be more fully apparent from the ensuing disclosure and appended claims.

### BRIEF DESCRIPTION OF THE DRAWINGS

FIG. 1 shows an exemplary cross-sectional view of a semiconductor device structure illustrating aspects of the present disclosure;

FIGS. 2A-2F illustrate cross-sectional views depicting a sequence of BEOL and FBEOL semiconductor manufacturing process steps to result in forming semiconductor SVIA structures used to connect metal structures of devices formed in different dielectric levels according to aspects of the present disclosure;

FIG. 2G illustrates a cross-sectional view of a final semiconductor structure that includes VFTL damascene metal vias and dual damascene metal “super vias” after CMP according to aspects of the present disclosure; and

FIG. 3 illustrates a cross-sectional view of a prior art semiconductor structure formed according to conventional methods that do not incorporate VFTL processing nor SVIA structures.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

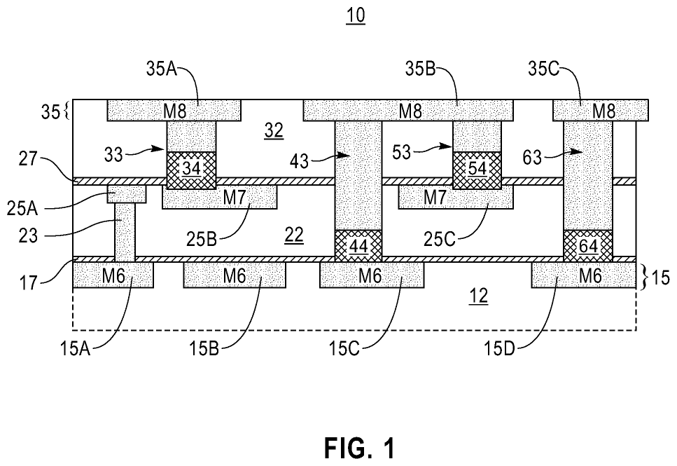

FIG. 1 shows an exemplary cross-sectional view of a semiconductor device structure 10 illustrating aspects of the present disclosure. As shown in FIG. 1, the structure 10 highlights (Far)-Back-End-Of-Line (BEOL and FBEOL) semiconductor manufacturing processes for fabricating conductive wiring, contacts, insulating material layers, metal levels, etc. that interconnect already formed individual devices such as logic circuitry components, which include, but are not limited to: capacitors, diodes, resistors, transistors, inductors, varactors, etc. (not shown). As shown in FIG. 1, the exemplary structure 10, includes: a metal layer 15 formed on a semiconductor structure including an inter-level dielectric (ILD) layer 12 of a low-k dielectric material such as an oxide dielectric material or a silicon doped oxide. In an embodiment, preferred ILD layer materials can include SiCOH, SICNH, porous silicates, carbon doped oxides, silicon dioxides, silicon oxynitrides, carbon-doped silicon oxide (SiCOH) and porous variants thereof, silsesquioxanes, siloxanes, or other dielectric materials having, for example, a dielectric constant in the range of about 2 to about 4. An SiCOH dielectric film having a dielectric constant (k) of about 2.7-2.8 can, for example, comprise one or more ILD layers. Further dielectric materials for ILD levels include ultra-low-k (ULK) dielectrics such as SiN or Tetracthyl orthosilicate, e.g., tetraethoxysilane (TEOS). Such a dielectric film can be deposited using plasma-enhanced chemical vapor deposition (PECVD).

Formed within the first inter-level dielectric material layer 12 is exemplary metal layer 15 patterned to include formed spaced apart metal structures 15A, 15B, . . . , 15D such as e.g., a metal wire, a line, a pad, a bar or like metal structure, e.g., that can be a formed after front end of line processing and during middle of line or back end of line processing. For non-limiting, illustrative purposes, metal structures 15A, . . . , 15D can be an “Mx−1^{th}” metal level. For non-limiting purposes of discussion, x=7, thus rendering metal structures 15A, . . . , 15D as a “M6” metallization line level structures. In embodiments, M6 metal level structures 15A, . . . , 15D are formed by conventional lithographic patterning, subtractive etching and metal material deposition processes. The metal structures 15A, . . . , 15D can be formed by deposition of a metal material such as Cu, Mo, Ru, W, Al, TiN or any other metal material with the need of a metal liner in some cases, followed by an electrochemical polish (CMP).

After a planarization of the top surface of ILD layer 12 and M6 metal level structures, there is formed a thin dielectric material cap layer 17 formed atop planarized top surfaces of the formed ILD 12 and “M6” metal level structures 15A, . . . , 15D. Further using conventional semiconductor deposition processes, formed above the thin dielectric material cap layer 17 is a further inter-level dielectric material layer 22 of a dielectric material (e.g., low-k or not). Further formed by conventional processes, within inter-level dielectric material layer 22, is a “next” metal level layer 25 patterned to include metal wire, line, pad, bar or like metal structures 25A, 25B, 25C. These metal structures 25A-25C form an “Mx^{th}” metal level (e.g., x=7 or “M7” metal line level) in the inter-level dielectric (ILD) material layer 22.

As shown in FIG. 1, formed within ILD level 22 between M6 and M7 metal level structures is a metal via structure, e.g., via 23, that is functional to provide a conductive interconnect within ILD layer 22 that connects example “M7” metal level structure 25A to a formed metal structure 15A at the example “M6” metal level. Metal via structure 23 is formed by conventional VFTL scheme and metallized at the same time with metal trench layer M7. Metallization of layer M7 and via 23 is formed by deposition of a metal material such as Cu, Mo, Ru, W, Al, TiN or any other metal material with the need of a metal liner in some cases followed by an electrochemical polish (CMP).

As further shown in the structure 10 of FIG. 1, after a planarization of the top surface of ILD layer 22 and M7 metal level structures, there is formed a thin dielectric material cap layer 27 formed atop planarized top surfaces of the formed ILD 22 and “M7” metal level structures 25A, . . . ,25D. After forming overlying dielectric material cap layer 27, a further dielectric (e.g., low-k or not) layer 32 is formed on top of the dielectric material cap layer 27. Further formed within dielectric layer 32 according to techniques of the present disclosure is a metal level layer 35 patterned to include further top metal structures 35A, 35B, 35C forming an “Mx+1^{th}” metal level (e.g., x=7 or “M8” metal line level) in the inter-level dielectric material layer 32. As shown, each further metal structure 35A, 35B, 35C of M8 metal line level connects to an underlying M7 metal line level structure or underlying M6 metal level structure via a respective super via (SVIA) contact with a metal plug formed therein according to embodiments herein. That is, as shown in FIG. 1, further top metal structure 35A of M8 metal level is electrically connected to a top surface of underlying M7 metal level structure 25B by a metal via 33 formed according to a modified VFTL dual damascene process in embodiments herein. Similarly, further top metal structure 35B of M8 metal level is electrically connected to a top surface of underlying M6 metal line level structure 15C by a super via (SVIA) 43 formed according to a modified VFTL dual damascene process and further top metal structure 35B of M8 metal level is electrically connected to a top surface of underlying M7 metal line level structure 25C by a metal via 53 formed according to a modified VFTL dual damascene process. Similarly, further top metal structure 35C of M8 metal level is electrically connected to a top surface of underlying M6 metal line level structure 15D by a SVIA 63 formed according to a modified VFTL dual damascene process. Thus, a super via (SVIA) can also be referred to as a “skip” via as the via interconnects metal structures at two metallization line levels while skipping over a metal structure at an intervening metallization line level. In embodiments herein, each respective via and SVIA structures 33, 43, 53, 63 is formed to include a respective metal plug, such as respective plugs 34, 44, 54, 64, e.g., made of cobalt (Co), Ruthenium (Ru), Molybdenum (Mo) and/or combinations and alloys thereof.

As shown in FIG. 1, after a damascene metal, e.g., copper, fill process, a subsequent chemical-mechanical-planarization (CMP) step is conducted resulting in formed M8 metal structures 35A, 35B, 35C having top surfaces co-planar with a top surface of ILD layer 32.

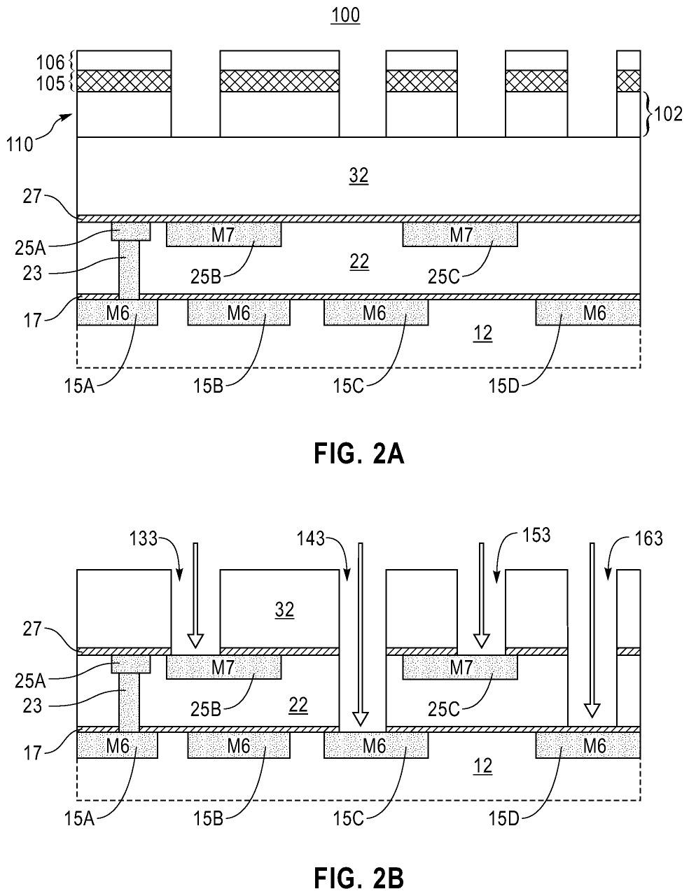

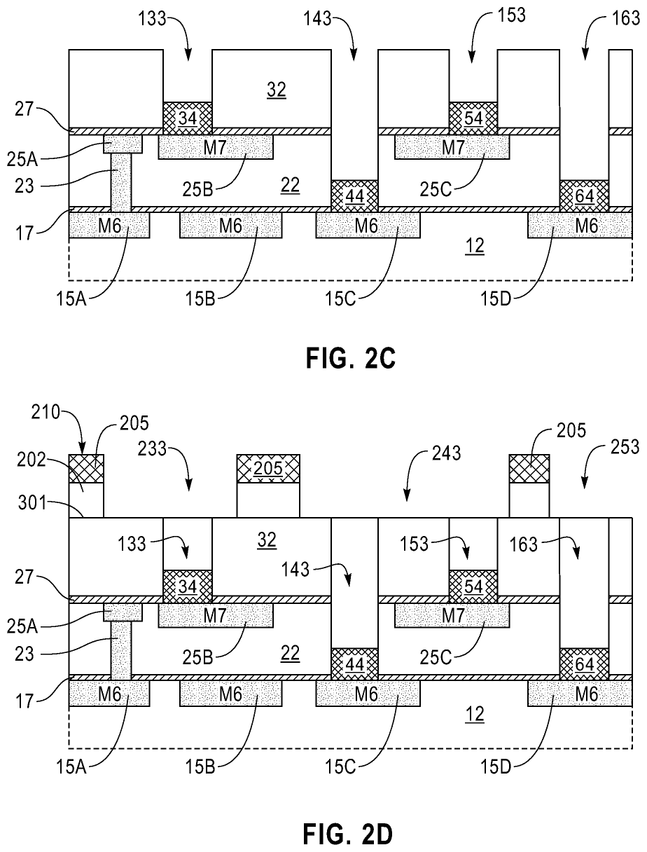

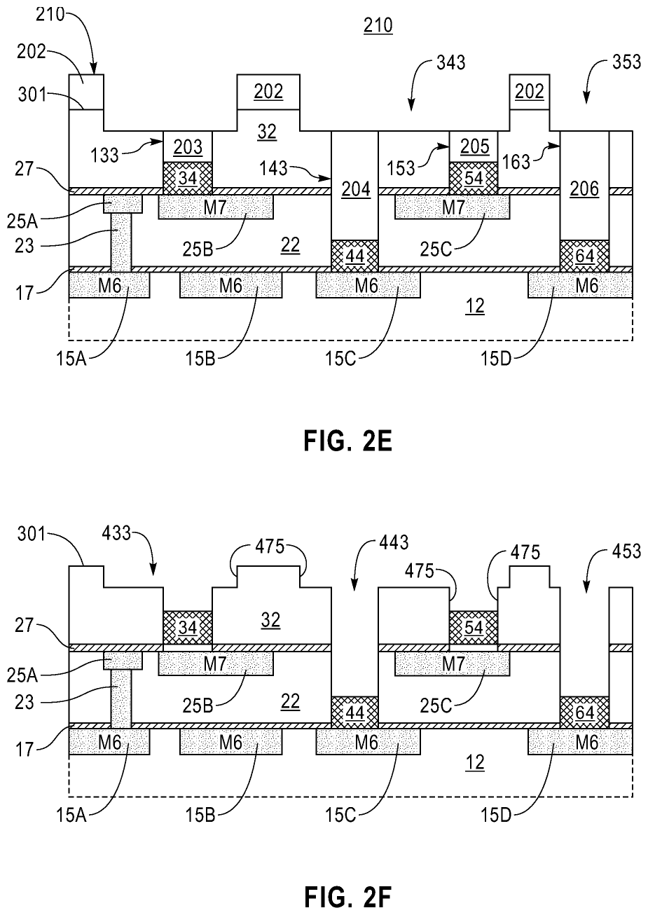

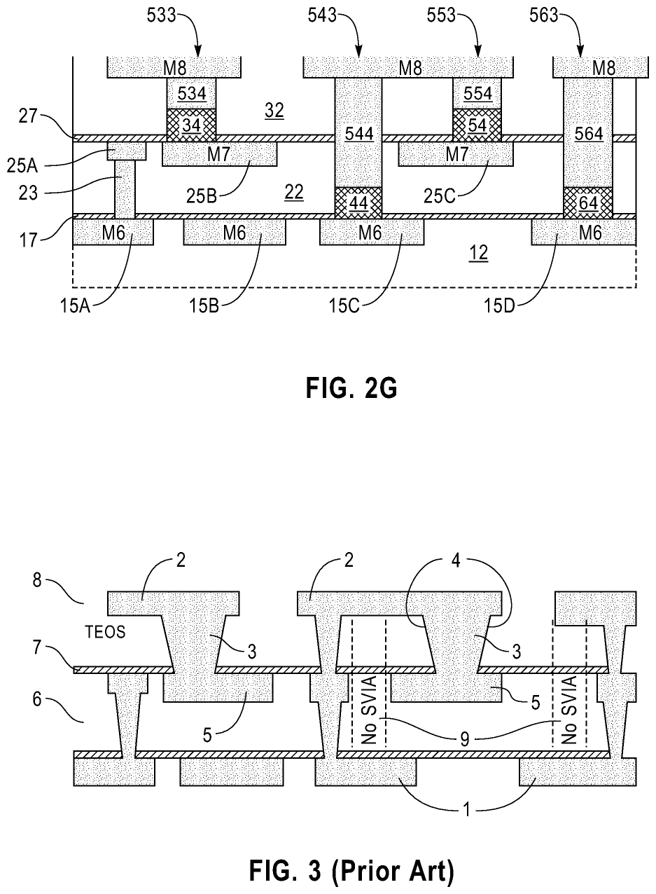

FIGS. 2A-2G illustrate cross-sectional views depicting a sequence of semiconductor manufacturing FBEOL process steps to result in intermediate semiconductor structures that result in final structures shown in FIG. 1 that include dual damascene metal “super vias” SVIAs directly interconnecting metal structures of different metal level layers to help reduce footprint and increase power delivery to lower metallization levels. These formed super vias have improved structural properties including a straight angle profile, i.e., are not chamfered.

As shown in FIG. 2A, there is depicted a cross-sectional view of an initial semiconductor structure 100. Initial structure 100 is formed of (middle of line) MOL or back end of line (BEOL) semiconductor manufacturing processes for fabricating conductive wiring, contacts, insulating material layers, metal levels, etc. that interconnect already formed individual devices such as transistors, capacitors, resistors, etc. (not shown). As shown in FIG. 2A, the exemplary structure 100, includes, from bottom to top: a first inter-level dielectric layer 12 of a low-k dielectric material, an overlying dielectric material cap layer 17 formed above the inter-level dielectric material layer 12 which can be a single or multi Etch stop layer (ESL) referred as “cap” layer or etch stop layer (ESL). In embodiments, the cap layer 17 can include a dielectric material, such as, for example, a suitable nitride or carbide, e.g., aluminum nitride (AlN), silicon nitride (SiN), silicon carbide (SiC), silicon carbonitride (SiCN), hydrogenated silicon carbide (SiCH), or other suitable material. In a preferred embodiment, the cap layer 17 can include an nBLoK™ layer (where nBLOK™ is a trademark of Applied Materials, Inc.). The cap layer 17 can have a vertical thickness ranging from about 1 nm to about 30 nm; a second inter-level dielectric material layer 22 of a low-k dielectric material formed above the dielectric material cap layer 17 and an overlying dielectric material cap layer 27 of the same materials and thicknesses as cap layer 17; and a top inter-level dielectric material (e.g., TEOS) layer 32 formed above the cap layer 27. In non-limiting embodiments, the ILD level TEOS layer(s) 12, 22, 32 can be formed of a thickness ranging between 100 nm to 5000 nm although lesser and greater thicknesses can also be employed.

As shown in FIG. 2A, connecting “Mx” level wiring metal structure 25A to Mx−1 level wiring structure 15A is a metal via 23 formed by conventional Via first trench last (VFTL) process. The via 23 can have a width ranging from about 10 nm to about 400 nm although lesser and greater thicknesses can also be employed and functions to provide a conductive interconnect from a Mx metal level structure to an underlying Mx−1 metal level structure formed in the first inter-level dielectric material layer 12.

In embodiments, the first inter-level dielectric material layer 12 and second inter-level dielectric material layer 22 can be a low-k dielectric material layer such as TEOS or any other material having a dielectric constant less than that of SiO₂. These inter-level dielectric material layers can be a hybrid dielectric structure that comprises at least two different dielectric materials. For example, layers 12 and 22 could be composed of two or more different dielectric layers in order to optimize the device R/C performance. For example, ILD layer 12 or 22 can be a two layer film: the bottom film optimized for the via performance with a height equivalent of the via and the top film optimized for the trench performance.

Formed within the first inter-level dielectric material layer 12 underlying dielectric material cap layer 17 are exemplary first line level (Mx−1) metal structures 15A, . . . , 15D, e.g., a metal wire, line, bar or like metal structure formed in the dielectric layer 12 and later refill by metal material such as Cu, Mo, Ru, W, Al, TiN or any other metal material with the need of a metal liner in some case, then follow by CMP (e.g., metal wiring structure). In an embodiment, these Mx−1 line level metal wirings can have a wire width ranging from about 9 nm to about 200 nm although lesser and greater thicknesses can also be employed. Similarly, formed within the second inter-level dielectric material layer 22 underlying dielectric material cap layer 27 are exemplary second line level (Mx) metal structures 25A, . . . , 25C, e.g., a metal wire, line, bar or like metal wiring structure formed in the dielectric layer 22 and later refill by metal material such as Cu, Mo, Ru, W, Al, TiN or any other metal material with the need of a metal liner in some case, then follow by CMP (e.g., metal wiring structure). In an embodiment, these Mx line level metal wirings can have a wire width ranging from about 9 to about 200 nm although lesser and greater thicknesses can also be employed.

FIG. 2A further depicts a structure resulting from further applied steps to pattern the mask layer stack 110 to locate and define initial features used to subsequently form VIA and SVIA metal structures in accordance with a VFTL dual damascene process. That is, formed atop the TEOS material layer 32 is a film layer 102, e.g., a an organic planarization (OPL) layer or OPL film 102, to be patterned as part of the VFTL dual damascene process. OPL layer can include material organic dielectric layer (ODL) material, spin-on carbon (SOC), etc. and can range from between 1000 nm to 5000 nm in thickness although lesser and greater thicknesses can also be employed. As shown in FIG. 2A, the method further includes depositing Silicon-containing anti-reflective coating (SiARC) or a low-temperature oxide (LTO) layer 105 ranging from between 5 nm to 100 nm in thickness on the OPL layer 102 although lesser and greater thicknesses can also be employed. Then the method includes forming a patternable photoresist layer 106 on the SiARC layer 105 using lithographic techniques. The SiARC layer 105 and the OPL 102 are then etched using layer 106 as mask to define the via and SVIA. To form via and super via structures with pitches below 50 nm, metal critical dimension (CD) shrinkage can be exploited, e.g., using different shrink techniques such as the use of highly polymerizing species (e.g., C₄F₈, SiCl₄, WF₆) or additional spacer. FIG. 2A shows the result of a first dry etch sequence where the SiARC 105 and OPL 102 has been etched to form mask stack 110. Eventually, SiARC, OPL and the resist layer 106 will be removed during a subsequent etch processes. The resist layer 106 will be removed during the OPL etch.

Referring to FIG. 2B, there is depicted a cross-sectional view of a structure resulting from further applied etching steps for simultaneous forming via openings 133, 153 and SVIA openings 143, 163. An etching step is performed using patterned mask layer pattern 110 wherein etching processes punch thru dielectric layer 32 and cap 27 for the formed Vias 133 and 153 and punches through dielectric layer 32, cap 27, dielectric layer 22 and cap layer 17 for the SVIAs 143 and 163. In embodiments, a single etch or multiple etching can be performed to provide the resulting patterned via openings 133, 143, 153, 163 illustrated in FIG. 2B. The etch or multiple etches is selective to the underlying copper metal. The dry etch can be a reactive ion etch process, a plasma etch process, ion beam etching or laser ablation. As a result of the etching steps, surfaces of the underlying Mx copper metal lines 25B, 25C and Mx−1 copper metal lines 15C, 15D are exposed within each of the formed openings 133, 143, 153 and 163. During the Via and SVIA etching the Siarc layer 105 is remove during a burn-off process.

Referring to FIG. 2C, there is depicted a cross-sectional view of a further structure resulting from further applied “self-deposition” or “self-forming” process steps to selectively deposit a metal “plug” to wholly contact the exposed copper metal structure surfaces within each of the formed via openings 133, 153 and SVIA openings 143, 163. In an embodiment, one or more conventional metal material deposition steps such as, for example, by electroless deposition process (e.g., electroless chemical plating or ECP) in which the metal surface catalyzes the oxidation of a reducing agent thereby releasing electrons for the metal deposition from the solution through a reduction reaction. It is a selective plating of a metal without applying an external current to form metal plugs 34, and 54 within respective openings 133, 153 and metal plugs 44 and 64 within respective openings 143, 163. In an embodiment, the metal plug is self-deposited and is formed by a cobalt metal that prevents copper attack or diffusion such as galvanic effect or resist poisoning. That is, the use of metal plug provides a protection to galvanic effect and resist poisoning the same way that the Cap layer would have done in the VFTL scheme when the Via etch will stop on the Cap layer. In embodiments, the metal (e.g., cobalt) plug is deposited to a thickness or height ranging from between 5 nm-50 nm although lesser and greater thicknesses or heights can also be employed.

Referring to FIG. 2D, there is depicted a cross-sectional view of a further structure resulting from further applied “trench last” lithography steps (i.e., trench patterning) including the depositing of a mask stack and the forming of a “trench last” lithography mask 210 used for subsequently forming dual damascene via and super via top trench structures using the structure of FIG. 2C. In an embodiment, there is first deposited OPL material 202 within formed via openings 133, 153 and SVIA openings 143, 163. In an embodiment, the OPL layer 202 is self-planarizing material such as an organic material including C, O, and H. The formulation of the OPL can be selected to provide sufficiently low viscosity so that a top surface of the OPL is self-planarizing over underlying topographic features. In some embodiments, the self-planarizing material of the OPL is an amorphous carbon layer. The OPL material 202 is deposited to fill each via and super via opening contacting the respective top surface of the metal plug therein and extend upward such that a thin OPL layer 202 is formed above and covers the surface of the second ILD layer 32. In this embodiment, the deposited OPL material avoids direct contact with the underlying bottom copper within each via/SVIA to be formed due to the presence of the plug. A further SiARC material layer 205 is formed atop the thin OPL layer 202. Although not shown in FIG. 2D, an additional resist mask formed by lithography is formed and exposed. At this step of FIG. 2D, the resist has been etched away or burned off during the partial OPL etch shown in FIG. 2D. Using subsequent SiARC layer 205 as hard mask, a dry etch process step forms a pattern of trenches 233, 243 and 253 within the OPL material level 202 that lands on dielectric layer 32 thereby forming a top “trench last” mask pattern 210. In an embodiment, the patterned trench 233 is formed in OPL level 202 directly above the via opening 133 and is dimensioned wider than, i.e., extends beyond, the edges defining the via opening 133. Similarly, the patterned trench 243 is formed within OPL level 202 is dimensioned to have a width wider than, i.e., extending beyond, the outer edges of the underlying respective formed super via (SVIA) opening 143 and via opening 153, and the trench 253 is formed in OPL level 202 above the via opening 163 and is of a width extending beyond the edges of SVIA opening 163. In the embodiment, the OPL layer is not in direct contact with any underlying bottom Copper structures 25B, 25C, of the Mx metal level and is not in direct contact with the underlying Copper structures 15C, 15D of the Mx−1 metal level thereby avoiding any amine contamination.

Referring to FIG. 2E, there is depicted a cross-sectional view of a further structure resulting from a further applied dielectric trench opening etch step to form the top trench portions of the VFTL dual damascene process using the structure of FIG. 2D. In an embodiment, using the lithographically patterned hard mask 210 of FIG. 2D, a further timed dry chemical etch step, e.g., a timed RIE etching step is conducted to further recess the formed trenches 233, 243 and 253 removing portions of the underlying TEOS ILD layer 32 to a level below a top surface 301 of the ILD layer 32. The recess distance below the TEOS layer 32 top surface 301 defines the depth of the formed metal trench, e.g., from 20 to 300 nm. This timed etching produces a structure used to form top VFTL trench opening 333 from the patterned trench 233 above filled via opening 133, form top VFTL trench opening 343 from the patterned trench 243 above filled via opening 143 and above filled super via opening 153, and form top VFTL trench opening 353 from the patterned trench 253 above filled super via opening 163. The etching of the top VFTL trenches may be timed to remove portions of the ILD layer 32 below the surface 301 while leaving a portion 203 of the OPL layer 202 in the filled via opening 133, leaving a portion 204 of the OPL layer 202 in the filled super via opening 143, leaving a portion 205 of the OPL layer 202 in the filled via opening 153 and leaving a portion 206 of the OPL layer 202 in the filled via opening 163. It is noted that during the dielectric etch sequence to open layer 32 to form the trench 333, 343, and 354, the SiARC layer 205 is removed at the same time by burn off.

Referring to FIG. 2F, there is depicted a cross-sectional view of a further structure resulting from a further applied “OPL strip” step in which etching is performed to completely remove the remaining OPL layer 202, 203, 204, 205 and 206 from the structure of FIG. 2E. Thus, using an etch process selective to the cobalt plug and Dielectric layers 22, 32, removed from each formed via opening 133, 153 and removed from each formed SVIA opening 143 and 163 are respective remaining OPL portions leaving respective metal material plugs 34, 54 in the via openings and metal plugs 44, 64 in the SVIA openings and exposing top surfaces of the metal plugs within each opening. As a result of removing the OPL structures 202, 203 and top SiARC layer 205 of hard mask 210 there remains opening 433 for forming a VFTL feature structure that will include a via portion; similarly there remains opening 443 for forming a further VFTL feature structure that will include a spaced apart via and SVIA portion; and there remains opening 453 for forming a VFTL feature structure that will include an SVIA portion. OPL layers 202, 203, 204, 205 and 206 can be removed for example by an etch plasma composed of N2/H2, CO/CO2, O2 to achieve high selectivity over the dielectric and metallic layers. In this etching process, while removing the remaining OPL, there is no cap layer portion 17 and 27 exposed nor cap layer punch through required. Thus, the slope of the via edge, i.e., the via edge or chamfer angles 475 of the via is straighter than can be produced in conventional methods because no final dielectric cap layer is opened during final trench etch.

In an embodiment, the trench pattern etching shown in FIG. 2E and OPL removal shown in FIG. 2F can be conducted as a single timed dry etching process.

Referring to FIG. 2G, there is depicted a cross-sectional view of a final structure resulting from a subsequently applied metallization step to form VFTL SVIAs and a final surface chemical-mechanical polishing (CMP) step. In particular, using conventional metal material deposition technique including, for example, chemical vapor deposition (CVD), plasma enhanced chemical vapor deposition (PECVD), physical vapor deposition (PVD), first a metal liner is deposited (e.g., TaN, Ti, TiN, Ru, Mo, . . . ) and later by electroplating or other type of deposition techniques, Copper is deposited over the structure in the structure of FIG. 2F to form Mx+1 metal level, e.g., M8, metal structures and respective vias or SVIAs for connecting to underlying Mx metal level structures and Mx−1 metal level structures, respectively. In an embodiment, a blanket metal material deposition process deposits within the VFTL trench and via feature opening 433 of FIG. 2F a metal material, e.g., metal liner and electroplating copper, to form the final VTFL structure 533 having top trench and a metal via portion 534 including metal plug 34, e.g., cobalt, contacting the underlying metallization structure 25B of the underlying Mx metallization level. Similarly, within the VFTL trench and via feature opening 443 of FIG. 2F is deposited a metal material, e.g., metal liner and electroplating copper, to form the final VTFL structure 543 having a metal trench and metal SVIA portion 544 including metal plug 44 contacting the underlying metallization structure 15C of the Mx−1 metallization level and simultaneously form final VTFL structure 553 having a metal trench and via portion 554 including metal plug 54, e.g., cobalt, contacting the underlying metallization structure 25C of the Mx metallization level. Similarly, within the VFTL trench and via feature opening 453 of FIG. 2F is deposited a metal material, e.g., metal liner and electroplating copper, to form the final VTFL structure 563 having a trench and SVIA portion 564 including metal plug 64 (e.g., cobalt) contacting the underlying metallization structure 15D of the Mx−1 metallization level.

FIGS. 2A-2G thus highlight method steps for forming an IC chip according to embodiments of the present invention. These highlighted steps result in semiconductor device structures that include VTFL dual damascene process trench via and super via structures for BEOL and Far BEOL processing. These method steps for SVIA formation using VFTL as described in FIGS. 2A-2G are beneficial in that there is no need to perform a punch through of the cap layers 17, 27 and results in a structure that exhibits a straighter via profile and chamfer. The chamfer is straighter because no dielectric cap layer is open during final Dieletric trench etch. Further, the provision of SVIAs help to reduce semiconductor device footprint and enabling direct access to lower metallization levels with increased power deliver. Such method steps and resulting IC device structures utilizes the underutilized space in IC chips and allows further size reduction of the IC chips without adversely impacting the device performance. Further, the method is much easier and cheaper than a two mask solution which requires two metal fill steps and CMP steps.

While FIGS. 2A-2G illustratively demonstrate exemplary structures and processing steps, according to specific embodiments of the present invention, it is clear that a person ordinarily skilled in the art can readily modify such structures or process steps for adaptation to specific application requirements, consistent with the above descriptions.

It should therefore be recognized that the present invention is not limited to the specific embodiment illustrated hereinabove, but rather extends in utility to any other modification, variation, application, and embodiment, and accordingly all such other modifications, variations, applications, and embodiments are to be regarded as being within the spirit and scope of the invention.

What is claimed is:

1. A method of forming a semiconductor structure comprising:
providing an initial semiconductor structure comprising a stack of inter-level dielectric (ILD) material layers including a top ILD layer, a bottom ILD layer and one or more intermediate ILD layers therebetween, one or more ILD material layers of the stack including a metallization level of metal structures;
forming via openings in the top ILD material layer, the corresponding formed via opening located above a corresponding metallization level metal structure of an underlying ILD layer of the stack, at least one via opening extending through two or more intermediate ILD material layers of said stack, each formed via opening extending to expose a surface of the corresponding metallization level metal structure in the underlying ILD level;
depositing, within each formed via opening, a metal material to form a metal plug having a top surface below a top surface of the corresponding formed via opening, the deposited metal plug material in the formed via opening directly contacting a top surface of the corresponding metallization level metal structure;
forming an organic planarization (OPL) layer above the top ILD layer, the OPL layer extending to completely fill each formed via opening;
forming one or more trench openings at a top surface of the formed OPL layer, each trench opening formed directly above a corresponding formed via opening;
stripping the OPL layer including removing the OPL material within each formed via opening;
forming corresponding top metallization level trench openings at a surface of said top ILD material layer; and
depositing a metal material within each corresponding top metal level trench openings in said third ILD layer and within a remaining space of each formed via opening.

2. The method of claim 1, wherein said forming the via openings in said top ILD material layer comprises:
forming a mask structure above the top ILD layer, the mask structure patterned to define features used to form the respective via openings located above the corresponding metallization level metal structure of an underlying ILD layer of the stack, and
etching using the patterned mask structure to form the corresponding via openings.

3. The method of claim 2 wherein said provided initial semiconductor structure further comprises:
a dielectric etch stop material layer formed between the bottom ILD layer and an intermediate ILD layer immediately above the bottom ILD layer of said stack, said dielectric etch stop material layer contacting a top surface of said metallization level metal structure in said bottom ILD layer of said stack, wherein said patterned mask structure etching etches a via opening through said top ILD layer and said intermediate ILD layers and through a portion of said dielectric etch stop material layer to expose a surface of said metallization level metal structure in said bottom ILD material layer.

4. The method of claim 3 wherein said deposited metal plug material is a different metal material than the metal material of said metallization level metal structure of said bottom ILD layer.

5. The method of claim 3, wherein said forming the one or more trench openings at a top surface of the formed OPL layer comprises:
forming a further mask structure above the OPL layer, said further mask structure patterned
to define features used to form the respective trench openings above each of the formed via openings; and
etching, using the further patterned mask structure, to obtain corresponding trench openings formed above a via opening.

6. A semiconductor structure comprising:
a first inter-level dielectric (ILD) material layer including a first metallization level of metal structures;
a second ILD material layer formed atop the first inter-level dielectric material layer, the second inter-level dielectric material layer including a second metallization level of metal structures;
a third ILD material layer formed atop the second inter-level dielectric material layer, the third inter-level dielectric material layer including a third metallization level of metal structures;
a metal via structure directly interconnecting a third metallization level metal structure to a top surface of a second metallization level metal structure in said second ILD material layer, said metal via structure comprising a top portion of a first metal material and a bottom portion of a second metal material connecting said top surface of the second metallization level metal structure; and
a metal super via (SVIA) structure directly interconnecting a third metallization level metal structure to a top surface of a first metallization level metal structure in said first ILD material layer, said metal SVIA structure comprising a top portion of a first metal material and a bottom portion of a second metal material connecting said top surface of the first metallization level metal structure.

7. The semiconductor structure as claimed in claim 6, wherein the first metal material is copper and the second metal material is a metal selected from the group comprising: cobalt, ruthenium, molybdenum or combinations and alloys thereof.

8. The semiconductor structure as claimed in claim 6, wherein the metal via structure and metal SVIA structure have a straight profile.

9. The semiconductor structure as claimed in claim 6, wherein the metal via structure and metal SVIA structure have no chamfered edges.

10. The semiconductor structure as claimed in claim 6, further comprising:
a first dielectric cap layer formed between said first inter-level dielectric material layer and said second inter-level dielectric material layer; and
a second dielectric cap layer formed between said second inter-level dielectric material layer and said third inter-level dielectric material layer.

11. The semiconductor structure as claimed in claim 6, wherein a single metal structure of said third metallization level of metal structures comprises:
a metal via structure directly interconnected to a top surface of a second metallization level metal structure in said second ILD material layer; and
a metal super via (SVIA) structure directly interconnected to a top surface of a first third metallization level metal structure in said first ILD material layer.

12. The semiconductor structure as claimed in claim 6, wherein each third metallization level metal structure and directly interconnected metal via structure is formed using a via first trench last damascene process.

13. The semiconductor structure as claimed in claim 6, wherein each third metallization level metal structure and directly interconnected metal SVIA structure is formed using a via first trench last damascene process.

14. A method of forming an integrated circuit (IC) device comprising:
providing an initial semiconductor structure comprising a first inter-level dielectric (ILD) material layer including a first metallization level of metal structures and a second ILD material layer formed atop the first inter-level dielectric material layer, the second inter-level dielectric material layer including a second metallization level of metal structures;
forming a third ILD material layer formed atop the second inter-level dielectric material layer;
forming via openings in said third ILD material layer, the corresponding formed via opening located above a corresponding second metallization level metal structure and extending to expose a surface of said second metallization level metal structure in said second ILD material layer;
forming super via openings in said third ILD material layer, said formed super via opening extending through said second ILD material layer located above a corresponding first metallization level metal structure and exposing a surface of said first metallization level metal structure in said first ILD material layer;
depositing, within each formed via and super via opening, a metal material to form a plug of a pre-determined height below a surface of the corresponding via or super via opening, the formed metal plug in the via opening directly contacting a top surface of a corresponding second metallization level metal structure and the formed metal plug in the super via opening directly contacting a top surface of a corresponding first metallization level metal structure;
depositing, within remaining space of each formed via and super via opening, an organic planarization layer (OPL) material that completely fills each via and super via opening and extends to form an OPL layer above the third ILD material layer;
forming top metal level trench openings at a top surface of the formed OPL layer, each top metal level trench opening formed directly above a corresponding formed via or super via opening in the third ILD material layer;
stripping the OPL layer including removing the OPL material within each opening;
forming corresponding top metal level trench openings at a top surface of said third ILD material layer; and
depositing a metal material within each corresponding top metal level trench openings in said third ILD layer and within a remaining space of each formed via and super via opening.

15. The method of claim 14, wherein said forming the via and super via openings in said third ILD material layer comprises:
forming a mask layer above the third ILD layer;
patterning the mask layer to define features to form the respective via and super via openings located above a corresponding second metallization level metal structure and first metallization level metal structures, and etching using the patterned mask layer to form the corresponding via and super via openings.

16. The method of claim 15, wherein said provided initial semiconductor structure further comprises:
a first dielectric cap layer formed between the first ILD material layer and second ILD material layer and contacting a top surface of said first metallization level metal structures; and
a second dielectric cap layer formed between the second ILD material layer and the third ILD material layer and contacting a top surface of said second metallization level metal structures, wherein said patterned mask etching etches through a portion of said first dielectric cap layer to expose a surface of said first metallization level metal structure in said first ILD material layer and etches through a portion of said second dielectric cap layer to expose a surface of said second metallization level metal structure in said second ILD material layer.

17. The method of claim 14 wherein said deposited metal material is a different metal material than the metal material of said first metallization level metal structure and second metallization level metal structure.

18. The method of claim 14, wherein said forming the top metal level trench openings at a top surface of the formed OPL layer comprises:
forming a further mask layer above the OPL layer;
patterning the further mask layer to define features to form the respective trench openings above each of the formed via and super via openings; and
etching, using the further patterned mask layer, to obtain corresponding trench openings formed above a via and super via openings.

19. The method of claim 18, wherein the further patterned mask layer defines a further feature to form a single trench opening above a formed via and super via opening, and
etching, using the further patterned mask layer, to obtain a single corresponding trench opening formed above both a formed via and super via opening.

20. The method of claim 19, wherein said stripping the OPL layer further comprises:
removing the OPL material within each opening, said OPL stripping forming corresponding top metal level trench openings at a top surface of said third ILD material layer.
